(19) United States
(12) Patent Application Publication
(10) Pub. No.: US 2025/0171294 A1
(43) Pub. Date: May 29, 2025

(54) MEMS THIN MEMBRANE WITH STRESS STRUCTURE

(71) Applicant: STMICROELECTRONICS PTE LTD, Singapore (SG)

(72) Inventors: Ravi Shankar, Singapore (SG); Tien Choy Loh, Singapore (SG); Ananya Venkatesan, Singapore (SG)

(73) Assignee: STMICROELECTRONICS PTE LTD, Singapore (SG)

(21) Appl. No.: 19/033,227

(22) Filed: Jan. 21, 2025

Related U.S. Application Data
(62) Division of application No. 17/115,137, filed on Dec. 8, 2020.
(60) Provisional application No. 62/961,510, filed on Jan. 15, 2020.

(51) Int. Cl. B81B 3/00; G01L 1/18; G01L 9/00

(52) U.S. Cl. CPC B81B 3/0021; G01L 1/18; G01L 9/0073; B81B 2201/0264; B81B 2203/0127

(57) ABSTRACT

A blind opening is formed in a bottom surface of a semiconductor substrate to define a thin membrane suspended from a substrate frame. The thin membrane has a topside surface and a bottomside surface. A stress structure is mounted to one of the topside surface or bottomside surface of the thin membrane. The stress structure induces a bending of the thin membrane which defines a normal state for the thin membrane. Piezoresistors are supported by the thin membrane. In response to an applied pressure, the thin membrane is bent away from the normal state and a change in resistance of the piezoresistors is indicative of the applied pressure.

### CROSS REFERENCE TO RELATED APPLICATION

This application is a divisional of United States Application for patent Ser. No. 17/115,137, filed Dec. 8, 2020, which claims priority from United States Provisional Application for Patent No. 62/961,510 filed Jan. 15, 2020, the disclosures of which are incorporated by reference.

### TECHNICAL FIELD

The present invention generally relates to miniature sensors and, in particular to a microelectromechanical system (MEMS) pressure sensor.

### BACKGROUND

There are many applications which require the sensing of pressure. It is known in the art to use a suspended membrane as a pressure sensor. However, the performance of such sensors in terms of sensitivity and range is less than optimal. There is a need in the art for a pressure sensor, especially one of the microelectromechanical system (MEMS) type, having improved sensitivity and range.

### SUMMARY

In an embodiment, a sensor comprises: a semiconductor substrate having a top surface and a bottom surface and including a blind opening in the bottom surface which defines a thin membrane suspended from a substrate frame, wherein the thin membrane has a topside surface and a bottomside surface; a stress structure mounted to one of the topside surface or bottomside surface of the thin membrane to induce a bending of the thin membrane which defines a normal state for the thin membrane; and a plurality of piezoresistors supported by the thin membrane.

In an embodiment, a pressure sensor comprises: a semiconductor frame surrounding an opening; a semiconductor membrane suspended from the semiconductor frame over the opening; a plurality of piezoresistors supported by the semiconductor membrane; and a stress structure mounted to a topside surface of the semiconductor membrane and configured to induce a bending of the semiconductor membrane to produce a convex bottomside surface which defines a normal state for the semiconductor membrane; wherein the semiconductor membrane responds to an applied pressure at the convex bottomside surface by deforming from the normal state in a direction away from the applied pressure; wherein a resistance of the plurality of piezoresistors changes in response to the deformation of the semiconductor membrane.

In an embodiment, a pressure sensor comprises: a semiconductor frame surrounding an opening; a semiconductor membrane suspended from the semiconductor frame over the opening; a plurality of piezoresistors supported by the semiconductor membrane; and a stress structure mounted to a bottomside surface of the semiconductor membrane and configured to induce a bending of the semiconductor membrane to produce a convex topside surface which defines a normal state for the semiconductor membrane; wherein the semiconductor membrane responds to an applied pressure at the convex topside surface by deforming from the normal state in a direction away from the applied pressure; wherein a resistance of the plurality of piezoresistors changes in response to the deformation of the semiconductor membrane.

### BRIEF DESCRIPTION OF THE DRAWINGS

For a better understanding of the embodiments, reference will now be made by way of example only to the accompanying figures in which:

FIGS. 1-3 show steps of a process for forming a microelectromechanical system (MEMS) pressure sensor;

FIGS. 4-5 illustrate a response of the sensor of FIG. 3 to the application of pressure;

FIGS. 6-10B show steps of a process for forming a microelectromechanical system (MEMS) pressure sensor;

FIGS. 11A and 11B illustrate a response of the sensor of FIGS. 10A and 10B, respectively, to the application of pressure; and

FIGS. 12A-12C are plan views showing example layouts for the stress structure with piezoresistors in a bridge circuit configuration for the sensor.

### DETAILED DESCRIPTION

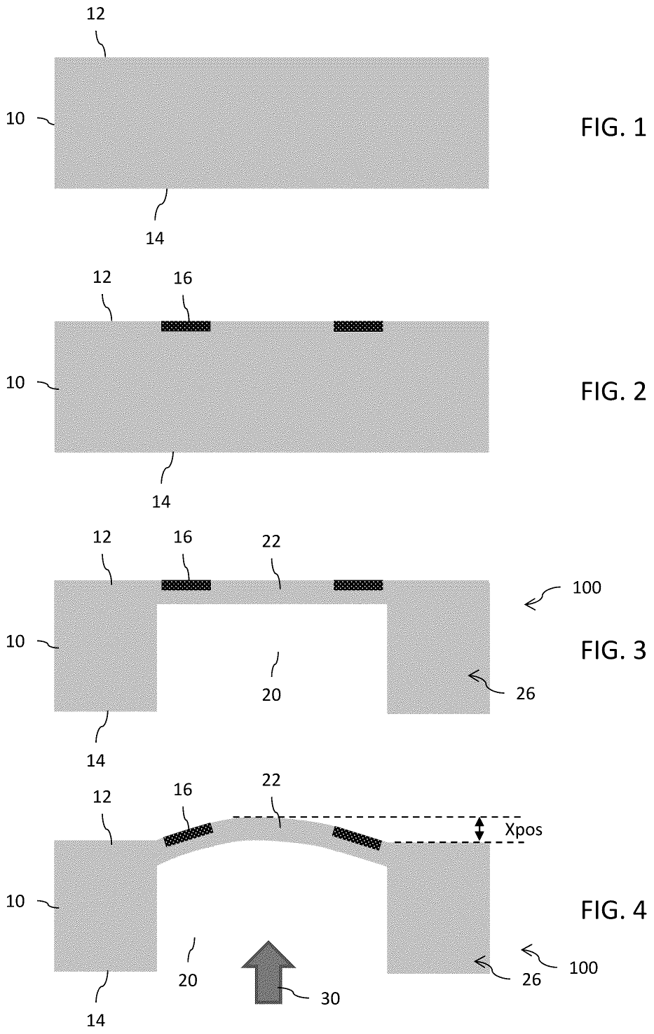

Reference is made to FIGS. 1-3 which show steps in a process for forming a microelectromechanical system (MEMS) pressure sensor 100. FIG. 1 shows a semiconductor substrate 10 that is, for example, made of silicon. The substrate 10 may, if desired, be lightly doped with a dopant of a first conductivity type (for example, n-type) or may be left as intrinsic semiconductor material. The substrate 10 includes a top surface 12 and a bottom surface 14. Using a conventional lithographic process, a plurality of doped regions 16 are formed in the substrate 10 at the top surface 12. The doped regions 16 may, for example, be formed using a masked implantation and activation of a dopant of a second conductivity type (for example, p-type). As an example, the doped regions 16 have a dopant concentration suitable for forming a resistive semiconductor structure. The result is shown in FIG. 2. The bottom surface 14 of the substrate 10 is then micromachined in order to selectively thin the substrate 10 and form a blind opening (or cavity) 20 extending into the substrate from the bottom surface 14, where the blind opening defines a thin membrane 22 at the top surface 12. The thin membrane 22 has a thickness which permits bending in response to application of a pressure to be sensed. The plurality of doped regions 16 are located within the area of the thin membrane 22 at the top surface 12. The result is shown in FIG. 3. The portions of the substrate 10 which are not thinned form a substrate frame 26 from which the thin membrane 22 is suspended. The substantially flat shape of the thin membrane 22 as shown in FIG. 3 is the normal or initial state of the sensor 100.

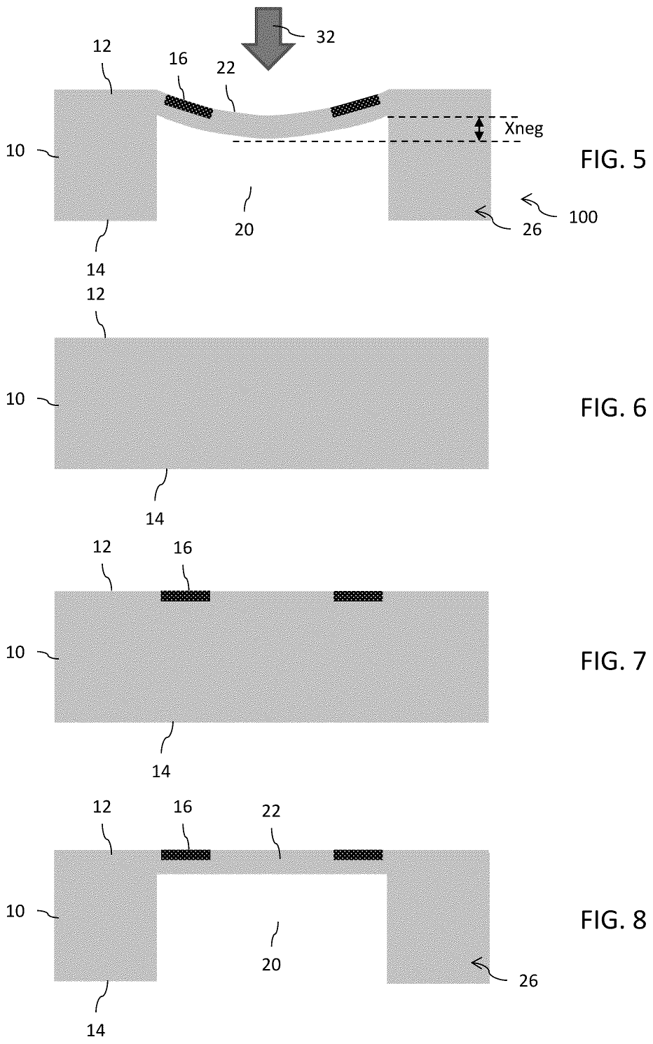

By making an electrical connection to the doped region 16 at two distinct, spaced apart, locations, each doped region 16 may form a semiconductor resistor (for example, of the piezoresistive type) such that the resistance between the two electrical connections varies as a function of displacement (i.e., bending) of the thin membrane 22. The thin membrane 22 may be bent in a first direction, away from the normal or initial state, in response to a pressure 30 applied in the direction of the bottom surface 14 as shown in FIG. 4. The amount of displacement Xpos by which the thin membrane 22 is bent is a function of the magnitude of the applied pressure 30, and the change of resistance of the piezoresistive resistors formed by the included doped regions 16 will correspondingly vary as a function of the magnitude of the applied pressure 30. The thin membrane 22 may also be bent in a second direction, opposite the first direction, away from the normal or initial state, in response to a pressure 32 applied to the top surface 12 as shown in FIG. 5. The amount of displacement Xneg by which the thin membrane 22 is bent is a function of the magnitude of the applied pressure 32, and the change of resistance of the piezoresistive resistors formed by the included doped regions 16 will correspondingly vary as a function of the magnitude of the applied pressure 32. It will be noted that the sensitivity range for the sensor 100 is limited by the maximum value of the amount of displacement (Xpos, or Xneg) due to the bending of the thin membrane 22.

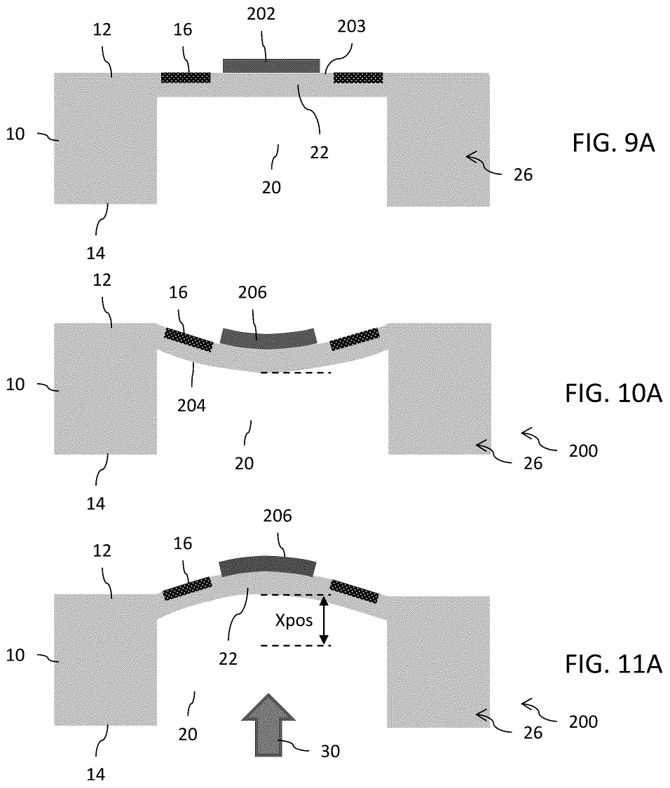

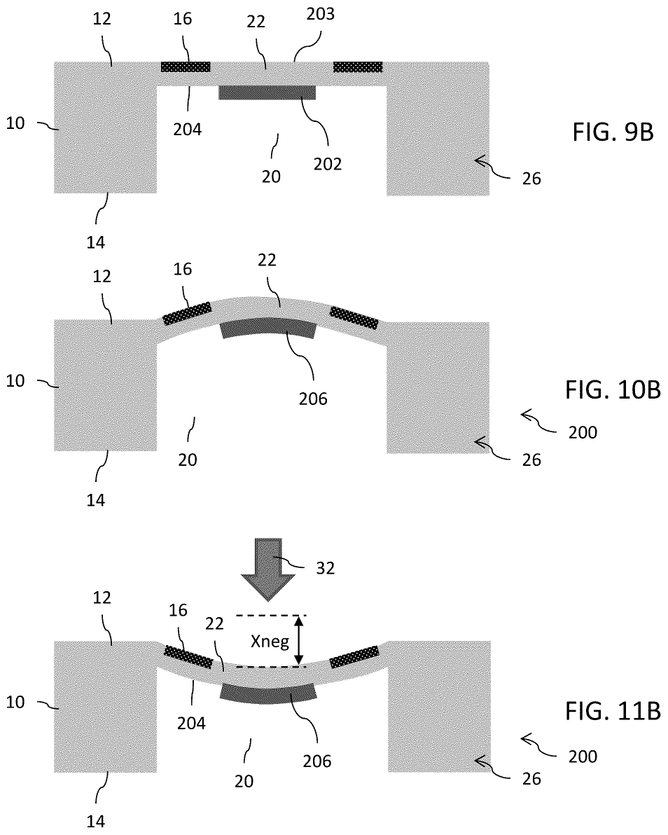

Reference is made to FIGS. 6-10B which show steps in a process for forming a microelectromechanical system (MEMS) pressure sensor 200. FIG. 6 shows a semiconductor substrate 10 that is, for example, made of silicon. The substrate 10 may, if desired, be lightly doped with a dopant of a first conductivity type (for example, n-type) or may be left as intrinsic semiconductor material. The substrate 10 includes a top surface 12 and a bottom surface 14. Using a conventional lithographic process, a plurality of doped regions 16 are formed in the substrate 10 at the top surface 12. The doped regions 16 may, for example, be formed using a masked implantation and activation of a dopant of a second conductivity type (for example, p-type). As an example, the doped regions 16 have a dopant concentration suitable for forming a resistive semiconductor structure. The result is shown in FIG. 7. The bottom surface 14 of the substrate 10 is then micromachined in order to selectively thin the substrate 10 and form a blind opening (or cavity) 20 extending into the substrate from the bottom surface 14, wherein the blind opening defines a thin membrane 22 at the top surface 12. The thin membrane has a thickness which permits bending in response to application of a pressure to be sensed. The plurality of doped regions 16 are located within the area of the thin membrane 22 at the top surface 12. The result is shown in FIG. 8. The portions of the substrate 10 which are not thinned form a substrate frame 26 from which the thin membrane 22 is suspended. Next, a layer 202 of a material is deposited on a topside surface 203 of the thin membrane 22 in the middle of the area of the thin membrane 22. The deposited material may, for example, comprise a polyimide. The area occupied by the layer 202 is less than the area of the thin membrane 22. The result is shown in FIG. 9A. A curing process is then performed with respect to the layer 202 and as a result the layer 202 shrinks to form a stress structure 206 which induces a deformation of the thin membrane 22 due to residual stress with a convex shape on the bottomside surface 204 of the thin membrane 22 (and a concave shape on the topside surface 203 of the thin membrane 22). The result is shown in FIG. 10A. The deformed shape of the thin membrane 22 as shown in FIG. 10A is the normal or initial state of the sensor 200. The curing process may comprise, after deposition of the layer 202, a prebake (for example, at a temperature of about 240° C.), followed by an exposure to ultra-violet light in a contact aligner (with a dose of about 420 mj), followed by an atmospheric oven bake (for example, at a temperature of about 350° C.).

In an alternative embodiment, the layer 202 of the material is deposited within the opening 20 on the bottomside surface 204 of the thin membrane 22 in the middle of the area of the thin membrane 22. Again the deposited material may comprise a polyimide, and the area occupied by the layer 202 is less than the area of the thin membrane 22. The result is shown in FIG. 9B. The curing process as discussed above is then performed to form a stress structure 206 which induces a deformation of the thin membrane 22 due to residual stress with a convex shape on the topside surface 203 of the thin membrane 22 (and a concave shape on the bottomside surface 204 of the thin membrane 22). The result is shown in FIG. 10B. The deformed shape of the thin membrane 22 as shown in FIG. 10B is the normal or initial state of the sensor 200.

It will be noted that in the normal or initial state of the sensor 200, for each of the embodiments shown by FIGS. 10A and 10B, the stress structure 206 is located on the surface of the thin membrane 22 which is associated with the concave shape as a result of the residual stress from the stress structure. The opposite surface of the thin membrane 22, which is associated with the convex shape, forms the pressure sensing surface of the sensor 200. Thus, in the FIG. 10A embodiment the bottomside surface 204 of the thin membrane 22 is the pressure sensing surface, while in the FIG. 10B embodiment the topside surface 203 of the thin membrane 22 is the pressure sensing surface. The use of the stress structure 206 forms a sensor where the thin membrane 22 is biased in a deformed shape for the normal or initial state, deflects from that deformed shape in response to an applied pressure at the convex shaped surface (in an opposite direction from the deformed shape) and is resilient so as to return to that deformed shape when the pressure is removed.

It is important to note that the thinning of the substrate 10 to form the blind opening 20 must be controlled so as to set the thickness of the thin membrane 22 in a manner which permits the stress structure 206 to induce the required degree of deformation of the thin membrane 22 for the normal or initial state.

By making an electrical connection to the doped region 16 at two distinct, spaced apart, locations, each doped region 16 may form a semiconductor resistor (for example, of the piezoresistive type) such that the resistance between the two electrical connections varies as a function of displacement (i.e., bending) of the thin membrane 22. With respect to the embodiment of the sensor 200 as shown in FIG. 10A, the thin membrane 22 may be bent in a direction opposite the biased deformation induced by the stress structure 206, which defines the normal or initial state, in response to a pressure 30 applied in the direction of the bottom surface 14 as shown in FIG. 11A. The amount of displacement Xpos by which the thin membrane 22 bends is a function of the magnitude of the applied pressure 30, and the change of resistance of the piezoresistive resistors formed by the included doped regions 16 will correspondingly vary as a function of the magnitude of the applied pressure 30. It will be noted that the magnitude of the displacement Xpos for the bending in FIG. 11A in response to the applied pressure is substantially greater (for example, at about 2X) the magnitude of displacement Xpos of the bending in FIG. 4. Thus, the sensor 200 exhibits a greater sensitivity and range than the sensor 100.

With respect to the embodiment of the sensor 200 as shown in FIG. 10B, the thin membrane 22 may be bent in a direction opposite the biased deformation induced by the stress structure 206, which defines the normal or initial state, in response to a pressure 32 applied in the direction of the top surface 12 as shown in FIG. 11B. The amount of displacement Xneg by which the thin membrane 22 bends is a function of the magnitude of the applied pressure 32, and the change of resistance of the piezoresistive resistors formed by the included doped regions 16 will correspondingly vary as a function of the magnitude of the applied pressure 32. It will be noted that the magnitude of displacement Xneg for the bending in FIG. 11B is substantially greater (for example, at about 2X) the magnitude of displacement Xneg of bending in FIG. 5. Thus, the sensor 200 exhibits a greater sensitivity and range than the sensor 100.

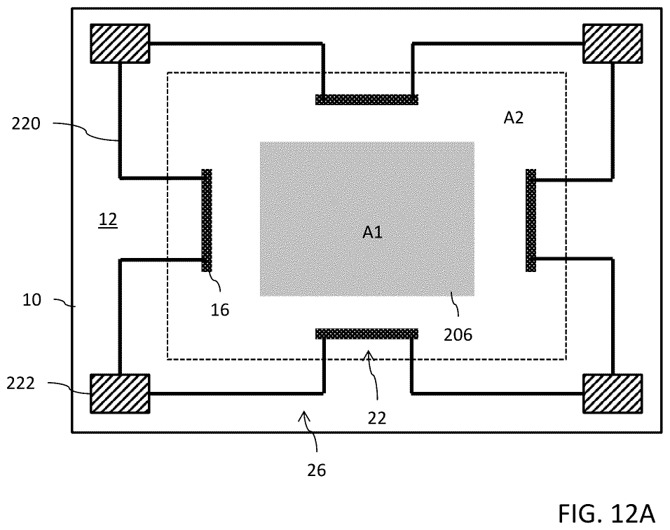

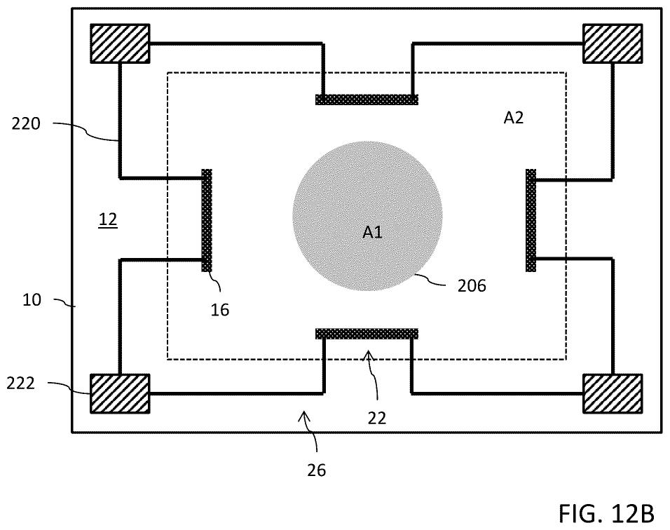

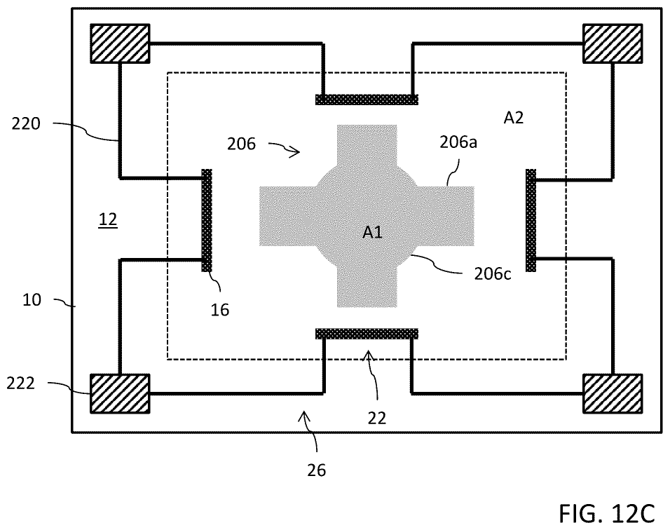

Reference is now made to FIG. 12A which is a plan view showing an example layout of the stress structure 206 with piezoresistors in a bridge circuit configuration for the sensor. The sensor includes four doped regions 16 forming four corresponding piezoresistors. The dotted line shows the area of the thin membrane 22 as defined by the opening 20. The stress structure 206 is shown in this view on the top surface 12 of the substrate 10 corresponding to the implementation of FIG. 10A. However, it will be understood that the stress structure 206 could alternatively be positioned on the bottomside surface 204 in the opening 20 as shown in the implementation of FIG. 10B.

The area A1 occupied by the stress structure 206 is less than the area A2 of the thin membrane 22. The stress structure 206 is offset from, and in a preferred embodiment centered between, the four doped regions 16. Indeed, in the preferred embodiment the geometric center of the area Al occupied by the stress structure 206 coincides with the geometric center of the area A2 occupied by the thin membrane 22. The thin membrane 22 defined by the opening 20 and the stress structure 206 may each have, in plan view, a quadrilateral shape. The four doped regions 16 are arranged to longitudinally extend parallel to a corresponding side of the stress structure 206. Furthermore, a center of the longitudinal extension of each doped region 16 is located in alignment with the center of corresponding side of the thin membrane 22 in order to ensure maximal stress.

Circuit lines 220 are formed above, and insulated from, the top surface 12 of the substrate 10, with those circuit lines 220 interconnecting electrical connection pads 222 of the sensor to the four doped regions 16 through vias (not explicitly shown, but located at positions to make electrical contact to the spaced apart locations for each doped region 16). The electrical circuit formed by the illustrated electrical connections forms a resistive bridge circuit, and variation in the resistance of the bridge circuit can be sensed using a sensing circuit connected to the pads 222 in order to sense the applied pressure 30, 32.

FIG. 12A shows the plan view for the stress structure 206 having a quadrilateral shape (which may be rectangular (as show) or square, for example). In an alternative implementation shown in FIG. 12B, the stress structure 206 has a round shape in the plan view (where that round shape may be circular or ovular). The circular shape of the stress structure, for example, induces circular residual stress on the thin membrane 22 and this will alter both the response of the membrane to the applied pressure 30, 32 and variation in resistance of the piezoresistors to that membrane response. In an alternative implementation shown in FIG. 12C, the stress structure 206 has a more complex shape in the plan view. The complex shape for the stress structure 206 comprises a central region 206c (which may have any desired shape including quadrilateral and round (as shown)) and one or more arms 206a which radially extend from the central region 206c. In a preferred implementation, each included radially extending arm 206a is oriented in a direction extending towards a corresponding one of the piezoresistors (that direction preferably being perpendicular to the longitudinal extension of the doped region forming the piezoresistor). The advantage of the complex shape for the stress structure 206 is that the arms 206a protrude residual stress further away from the geometric center of the thin membrane 22. It will be noted than an imbalance in the residual stress induced by the stress structure 206 can be applied by including less than four arms 206a and/or by having the included arms 206s present different radial lengths.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A sensor, comprising:
a semiconductor substrate having a top surface and a bottom surface and including a blind opening extending into the semiconductor substrate from the bottom surface, said blind opening defining a thin membrane suspended from a substrate frame, wherein the thin membrane has a topside surface and a bottomside surface;
a stress structure mounted to one of the topside surface or bottomside surface of the thin membrane and configured to induce a bending of the thin membrane which defines a normal state for the thin membrane;
wherein the stress structure, in plan view, has a round shape and further includes one or more arms which radially extend from the round shape; and
a plurality of piezoresistors supported by the thin membrane;
wherein each piezoresistor longitudinally extends parallel to a side of the stress structure, and a center of the longitudinally extending piezoresistor is located in alignment with a center of a corresponding side of the thin membrane.

2. The sensor of claim 1, wherein each piezoresistor is formed by a doped region at the topside surface of the thin membrane.

3. The sensor of claim 1, wherein the blind opening defines the thin membrane to have, in plan view, a quadrilateral shape.

4. The sensor of claim 1, wherein the stress structure is mounted to the topside surface of the thin membrane and the induced bending of the thin membrane forms a concave shape at the topside surface and a convex shape at the bottomside surface.

5. The sensor of claim 4, wherein the sensor functions to sense pressure applied in a direction towards the bottomside surface which produces a bending of the thin membrane away from the normal state, and wherein a resistance of the plurality of piezoresistors changes in response to said bending of the thin membrane away from the normal state.

6. The sensor of claim 1, wherein the stress structure is mounted to the bottomside surface of the thin membrane and the induced bending of the thin membrane forms a concave shape at the bottomside surface and a convex shape at the topside surface.

7. The sensor of claim 6, wherein the sensor functions to sense pressure applied in a direction towards the topside surface which produces a bending of the thin membrane away from the normal state, and wherein a resistance of the plurality of piezoresistors changes in response to said bending of the thin membrane away from the normal state.

8. A pressure sensing device comprising the sensor of claim 1.

9. A sensor, comprising:
a semiconductor substrate having a top surface and a bottom surface and including a blind opening extending into the semiconductor substrate from the bottom surface, said blind opening defining a thin membrane suspended from a substrate frame, wherein the thin membrane has a topside surface and a bottomside surface;
a stress structure mounted to one of the topside surface or bottomside surface of the thin membrane and configured to induce a bending of the thin membrane which defines a normal state for the thin membrane; and
a plurality of piezoresistors supported by the thin membrane;
wherein the stress structure, in plan view, has a quadrilateral shape, and sides of the stress structure extend parallel to sides of the blind opening; and
wherein each piezoresistor longitudinally extends parallel to a side of the stress structure, and a center of the longitudinally extending piezoresistor is located in alignment with a center of a corresponding side of the thin membrane.

10. The sensor of claim 9, wherein each piezoresistor is formed by a doped region at the topside surface of the thin membrane.

11. The sensor of claim 9, wherein the stress structure is mounted to the topside surface of the thin membrane and the induced bending of the thin membrane forms a concave shape at the topside surface and a convex shape at the bottomside surface.

12. The sensor of claim 11, wherein the sensor functions to sense pressure applied in a direction towards the bottomside surface which produces a bending of the thin membrane away from the normal state, and wherein a resistance of the plurality of piezoresistors changes in response to said bending of the thin membrane away from the normal state.

13. The sensor of claim 9, wherein the stress structure is mounted to the bottomside surface of the thin membrane and the induced bending of the thin membrane forms a concave shape at the bottomside surface and a convex shape at the topside surface.

14. The sensor of claim 13, wherein the sensor functions to sense pressure applied in a direction towards the topside surface which produces a bending of the thin membrane away from the normal state, and wherein a resistance of the plurality of piezoresistors changes in response to said bending of the thin membrane away from the normal state.

15. A pressure sensing device comprising the sensor of claim 9.
